(19) United States
(12) Patent Application Publication
(10) Pub. No.: US 2008/0081437 A1
(43) Pub. Date: Apr. 3, 2008

(54) Active device array substrate and cutting method thereof

(76) Inventors: Hsien-Sin Yeh, Padeh City (TW); Der-Chun Wu, Padeh City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(21) Appl. No.: 11/602,221

(22) Filed: Nov. 21, 2006

(30) Foreign Application Priority Data
Sep. 29, 2006 (TW) 95136287

(51) Int. Cl. H01L 21/00

(52) U.S. Cl. 438/460

(57) ABSTRACT

A structure of the active device array substrate and the cutting method thereof are provided. The leads laid on the surface of the active device array substrate to electrically connect the bond pads and the short rings have high transmittance for the laser light. After the large-scale active device array substrate and the large-scale CF substrate has been glued into a large-scale substrate, the outer rims of the terminal parts of the active device array substrate can be cut off by applying the full-body-cut method using a laser light.

### BACKGROUND OF THE INVENTION

1. Field of the Invention

The present invention relates to a structure of an active device array substrate and a cutting method thereof, and more particularly, to provide a structure of the active device array substrate and a cutting method thereof using a laser light.

2. Description of the Prior Art

The Thin Film Transistor-Liquid Crystal Display (TFT-LCD) is the most popular Flat Panel Display (FPD) nowadays. It has many merits such as its low power consumption, thin shape, light weight, and low driving voltage, etc.

Generally, a TFT-LCD panel is constituted by two substrates, an active device array substrate and a Color Filter (CF) substrate, having plural electrodes thereof. The active device array substrate is also called a TFT array substrate. The liquid crystal is filled between the two substrates. The electrical field formed between the electrode of the two substrates may affect the arrangement states of the liquid crystal, and so as to control the image brightness of the panel.

Presently, the large-scale glass substrates are widely used in the manufacturing process to lower down the production time and cost for elevating the productivity. It is to respectively accomplish the processes of several pieces of the active device array substrates and the CF substrates included in two corresponding large-scale glass substrates in advance, then gluing the two corresponding large-scale glass substrates into one large-scale substrate using the sealant. And then, the glued large-scale substrate is cut into several discrete panels to proceed the follow-up processes, such as the liquid crystal injection and the end seal, etc.

FIG. 1 is a schematic diagram of a glued large-scale substrate, the large-scale CF substrate 100 is glued on the large-scale active device array substrate 102. There will be four discrete panels 10, 20, 30, 40 after the cutting process. In FIG. 1, the “a-a′” and “d-d′” represent the non-terminal cutting routes, the large-scale CF substrate 100 and the large-scale active device array substrate 102 will be cut through after cutting. Besides, the “b-b′” and “e-e′” represent the inner rim cutting routes of the terminal parts, the large-scale CF substrate 100 will be cut to the interface glued to the large-scale active device array substrate 1 02 after cutting. In addition, the “c-c′” and “f-f′” represent the outer rim cutting routes of the terminal parts, the large-scale CF substrate 100 and the large-scale active device array substrate 102 will be cut through after cutting.

FIG. 2 is a schematic diagram of a discrete panel 10 after cutting, the CF substrate 12 is glued on the active device array substrate 14. There are exposed bond pads 16 which are used to electrically connect to the external driving circuits (not shown in the figure) on the surface of the active device array substrate 14, and the cut-off metal leads 18 are connected with the bond pads 16.

It is more and more popular to use the laser to cut the glued large-scale substrate today, and the laser cutting can be divided into two different methods: scribe-and-break and full-body-cut. The infra-red laser, such as the CO₂ laser with wavelength 10.6 micrometer, can just penetrate into the depth of several micrometers under the surface of the glass substrate. Therefore, it is suitable for the scribe-and-break method. On the other hand, the ultra-violate laser or the visible laser, such as the green YAG laser that has been frequency-doubled with wavelength 532 nanometer, can penetrate the glass substrate thoroughly by being absorbed about 15 percent of the incident energy which can cut through the glass substrate. Therefore, the full-body-cut method using the ultra-violate or visible laser is suitable for the non-terminal cutting routes of the large-scale active device array substrate.

FIG. 3 is a schematic diagram for cutting the outer rims of the terminal parts of the large-scale active device array substrate using the scribe-and-break method, the large-scale CF substrate 302 is glued on the large-scale active device array substrate 304 to form a large-scale substrate. On the surface of the large-scale active device array substrate 304, there are the bond pads 306 and the short rings 308 which are used to prevent the possible static-electricity damage during the manufacturing processes before cutting. The metal leads 310 are used to electrically connect the bond pads 306 and the short rings 308. The laser light 314 emitted from the laser head 312 is focused on the surface of the large-scale CF substrate 302 and moved along the cutting route 316, so the surface of the large-scale CF substrate 302 will crack along the cutting route 316. After the scribing process, the large-scale substrate will be turned over to make the large-scale active device array substrate 304 face upward and then the scribing process will be executed again on the surface of the large-scale active device array substrate 304.

Consequently, using the scribe-and-break method to cut the outer rims of the terminal parts of the large-scale active device array substrate needs to scribe twice and turn over once. The processes are complex and the tack time is long. Furthermore, turning over the large-scale substrate is easy to make it fractured or damaged.

On the other hand, if using the full-body-cut method to cut the outer rims of the terminal parts of the large-scale active device array substrate, the laser energy will be blocked by the metal leads which are used to electrically connect the bond pads and the short rings. Consequently, it can not effectively penetrate the glass to cut through.

### SUMMARY OF THE INVENTION

In order to solve the aforementioned problem of using the scribe-and-break method to cut the outer rims of the terminal parts of the large-scale active device array substrate, which are complex, time-consuming and risky; one object of the present invention is to provide an active device array substrate and a laser cutting method thereof. Thereby, the outer rims of the terminal parts of the active device array substrate can be cut off by applying the full-body-cut method using a laser light for the glued large-scale CF substrate and the large-scale active device array substrate.

In order to solve the aforementioned problem of using the full-body-cut method to cut the outer rims of the terminal parts of the large-scale active device array substrate that the laser energy will be blocked by the metal leads, which are used to electrically connect the bond pads and the short rings, and so as to be unable to penetrate through to cut off the large-scale substrate; one object of the present invention is to provide leads with high transmittance for the laser light on the surface of the large-scale active device array substrate to electrically connect the bond pads and the short rings. Thereby, the outer rims of the terminal parts of the active device array substrate can be cut off by applying the full-body-cut method using a laser light for the glued large-scale CF substrate and the large-scale active device array substrate.

Consequently, an active device array substrate and a laser cutting method thereof of the present invention can substantially reduce the tack time to lower down the production cost and effectively elevate the cutting yield and quality.

To achieve the objects mentioned above, one embodiment of the present invention is to provide leads with high transmittance for the laser light on the surface of the large-scale active device array substrate to electrically connect the bond pads and the short rings, thereby the outer rims of the terminal parts of the active device array substrate can be cut off by applying the full-body-cut method using a laser light for the glued large-scale CF substrate and the large-scale active device array substrate.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a schematic diagram of a glued large-scale substrate in the prior art;

FIG. 2 is a schematic diagram of a discrete panel after accomplishing the cutting process of the glued large-scale substrate shown in FIG. 1;

FIG. 3 is a schematic diagram for cutting the outer rims of the terminal parts of the large-scale active device array substrate using the scribe-and-break method in the prior art;

FIG. 4 is a schematic diagram of a large-scale active device array substrate according to one embodiment of the present invention; and

FIG. 5 is a schematic diagram for cutting the outer rims of the terminal parts of a large-scale active device array substrate by applying the full-body-cut method using a laser light according to one embodiment of the present invention.

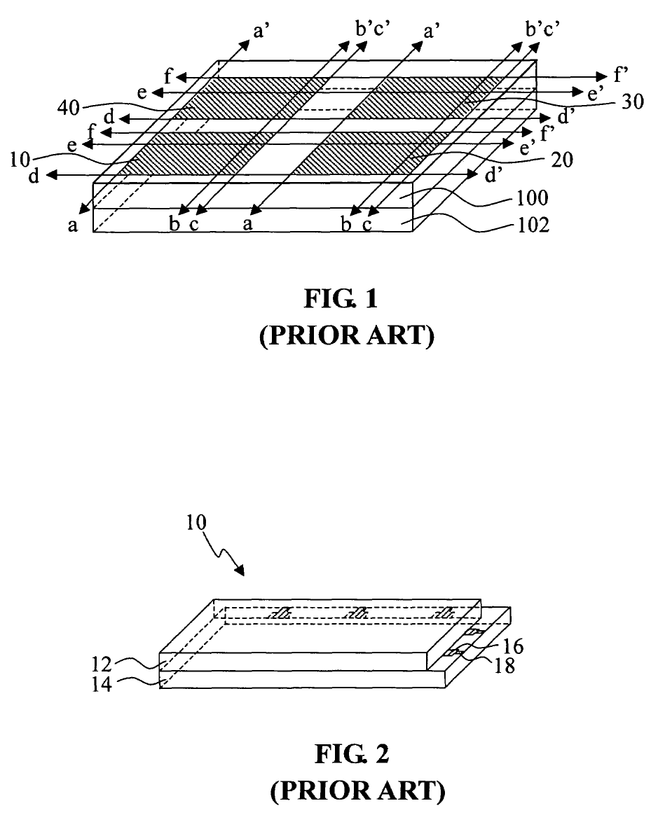

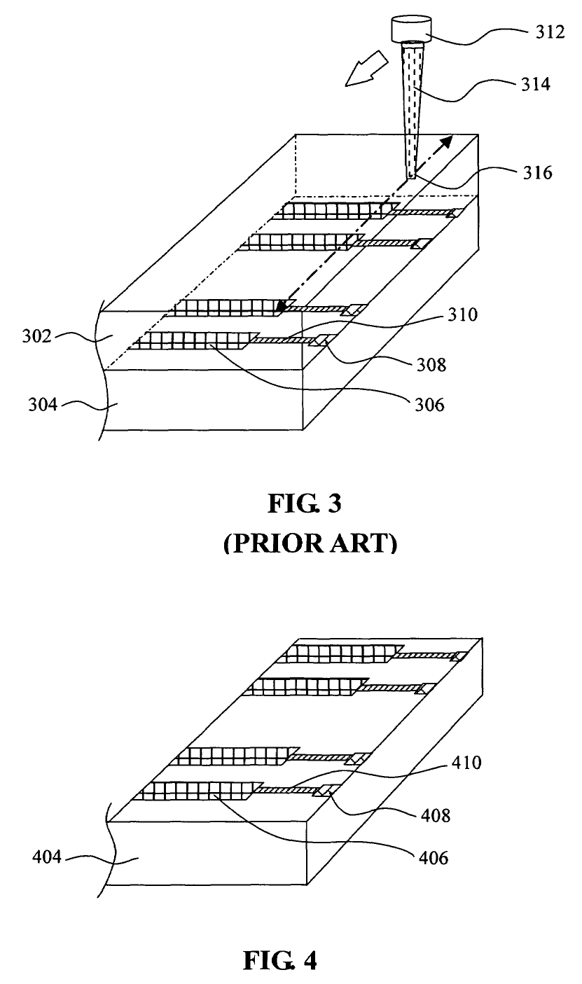

### DESCRIPTION OF THE PREFERRED EMBODIMENT

FIG. 4 is a schematic diagram of a large-scale active device array substrate according to one embodiment of the present invention. On the surface of the large-scale active device array substrate 404, there are bond pads 406 to electrically connect to the external driving circuits (not shown in the figure) and short rings 408 to prevent the possible static-electricity damage during the manufacturing processes before cutting. The leads 410 are used to electrically connect the bond pads 406 and the short rings 408, and the transmittance of the leads 410 is higher than which of the bond pads 406 and which of the short rings 408 for the laser light.

In one preferred embodiment, the material of the bond pads 406 and the short rings 408 is selected from the group consisting of Al, Cu, Au, Cr, Ta, Ti, Mn, Ni, Mo, Nb, Nd, Ag and a combination thereof.

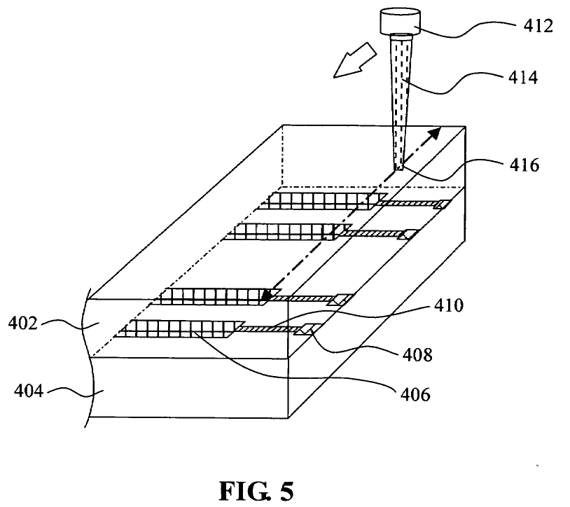

Because the leads 410 have high transmittance for the laser light, the full-body-cut method using a laser light can be used to cut the outer rims of the terminal parts of the large-scale active device array substrate. As shown in FIG. 5, the large-scale CF substrate 402 is glued on the large-scale active device array substrate 404, and the cutting route 416 passes the leads 410 on the surface of the large-scale active device array substrate 404. Therefore, the laser light 414 emitted from the laser 412 penetrates through the large-scale CF substrate 402, the leads 410 and the large-scale active device array substrate 404. After accomplishing the cutting process for the outer rims of the terminal parts, the large-scale CF substrate 402 and the large-scale active device array substrate 404 will be cut off along the cutting route 416.

In one preferred embodiment, the laser 412 is a Nd:YAG (Neodymium Doped Yttrium Aluminum Garnet) laser with wavelength 1064 nanometer or a green Nd:YAG laser that has been frequency-doubled with wavelength 532 nanometer. The material of the leads 410 is Indium Tin Oxide (ITO) or Indium Zinc Oxide (IZO).

Comparing with the scribe-and-break method of the prior art, the full-body-cut method according to the spirit of the present invention needs to irradiate the laser light only once and does not need to turn over the large-scale substrate. Therefore, the cutting process is much simpler and the tack time is substantially reduced, and so as to lower down the production cost. Furthermore, it does not risk the damage caused by turning-over the glass substrate, so it can effectively elevate the cutting yield and quality.

Consequently, one feature of the present invention is that the leads used to electrically connect the bond pads and the short rings on the surface of the large-scale active device array substrate have high transmittance for the laser light, thereby the outer rims of the terminal parts of the large-scale active device array substrate can be cut off by applying the full-body-cut method using a laser light for the glued large-scale CF substrate and large-scale active device array substrate according to the present invention.

The foregoing descriptions of specific embodiments of the present invention have been presented for purposes of illustrations and description. They are not intended to be exclusive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to particular use contemplated. It is intended that the scope of the invention be defined by the Claims appended hereto and their equivalents.

What is claimed is:

1. An active device array substrate, comprising:
a plurality of bond pads set on a surface of said active device array substrate;
a plurality of short rings set on said surface of said active device array substrate and distributed on the neighborhood of said bond pads; and
a plurality of leads set on said surface of said active device array substrate to electrically connect said bond pads and said short rings.

2. The active device array substrate according to claim 1, wherein the material of said bond pads and said short rings is selected from the group consisting of Al, Cu, Au, Cr, Ta, Ti, Mn, Ni, Mo, Nb, Nd, Ag and a combination thereof.

3. The active device array substrate according to claim 1, wherein the material of said leads is Indium Tin Oxide (ITO) or Indium Zinc Oxide (IZO).

4. A cutting method for a substrate, comprising:
providing an active device array substrate, which comprising:
a plurality of bond pads set on a surface of said active device array substrate;
a plurality of short rings set on said surface of said active device array substrate and distributed on the neighborhood of said bond pads; and
a plurality of leads set on said surface of said active device array substrate to electrically connect said bond pads and said short rings;
gluing a color filter substrate on said active device array substrate; and
irradiating a laser light to penetrate said leads along a cutting route to cut off said color filter substrate and said active device array substrate.

5. The cutting method according to claim 4, wherein the material of said bond pads and said short rings is selected from the group consisting of Al, Cu, Au, Cr, Ta, Ti, Mn, Ni, Mo, Nb, Nd, Ag and a combination thereof.

6. The cutting method according to claim 4, wherein the material of said leads is Indium Tin Oxide (ITO) or Indium Zinc Oxide (IZO).

7. The cutting method according to claim 4, wherein said laser light is emitted from a green Nd:YAG (Neodymium Doped Yttrium Aluminum Garnet) laser with wavelength 532 nanometer.

8. The cutting method according to claim 4, wherein said laser light is emitted from a Nd:YAG (Neodymium Doped Yttrium Aluminum Garnet) laser with wavelength 1064 nanometer.

9. The cutting method according to claim 4, wherein the transmittance of said leads is higher than which of said bond pads and which of said short rings for said laser light.
